(19) United States
(12) Patent Application Publication
(10) Pub. No.: US 2013/0187717 A1
(43) Pub. Date: Jul. 25, 2013

(54) RECEIVER EQUALIZATION CIRCUIT

(71) Applicants: Glenn A. Murphy, San Diego, CA (US); Nam V. Dang, San Diego, CA (US); Tirdad Sowlati, Irvine, CA (US); Xiaohua Kong, San Diego, CA (US)

(72) Inventors: Glenn A. Murphy, San Diego, CA (US); Nam V. Dang, San Diego, CA (US); Tirdad Sowlati, Irvine, CA (US); Xiaohua Kong, San Diego, CA (US)

(73) Assignee: QUALCOMM Incorporated, San Diego, CA (US)

(21) Appl. No.: 13/405,468

(22) Filed: Feb. 27, 2012

Related U.S. Application Data
(60) Provisional application No. 61/588,727, filed on Jan. 20, 2012.

(51) Int. Cl. H03F 3/16

(52) U.S. Cl. 330/304

(57) ABSTRACT

A receiver equalization circuit includes a first output transistor having a gate coupled to an input signal. The receiver equalization circuit may also include a second output transistor having a drain coupled to a drain of the first output transistor. The receiver equalization circuit may also include a resistor coupled between a gate and a drain of the second output transistor to provide a direct current (DC) bias to the gate of the second output transistor. The receiver equalization circuit may further include a feed-through capacitor coupled between the gate of the second output transistor and an input signal source. The feed-through capacitor feeds the input signal to the gate of the second output transistor when a frequency of the input signal is above a predetermined threshold. The feed-through capacitor and the resistor define a signal gain amplification point.

### CROSS-REFERENCE TO RELATED APPLICATION

This application claims the benefit under 35 U.S.C. §119(e) to U.S. Provisional Patent Application No. 61/588,727, entitled, RECEIVER EQUALIZATION CIRCUIT, filed on Jan. 20, 2012, in the names of MURPHY, et al., the disclosure of which is expressly incorporated by reference herein in its entirety.

### TECHNICAL FIELD

The present disclosure relates generally to receiver equalization. More specifically, the disclosure relates to an apparatus for extending a gain, bandwidth, and peaking ratio of a receiver equalization circuit.

### BACKGROUND

High speed serial interfaces, such as a Serial Advanced Technology Attachment (SATA) interface, serially transmit data between data storage devices and a host device/adapter over a communication channel. As signals propagate along the communication channel, the signals are subject to increasing losses that occur at higher and higher frequencies. These losses come from various sources including printed circuit board loading, connectors, chip package parasitics, on chip electrostatic discharge (ESD) structures, and the like.

As data transmission rates increase to 10 giga bits per second (Gbps) and beyond, new challenges and complexities in the design of advanced high speed interfaces are introduced. One of the challenges includes designing a receiver equalization circuit with sufficient gain and bandwidth to compensate for the increasing losses that occur at higher frequencies. Equalization techniques may be used in a data transceiver to compensate for the losses introduced by the communication channel and to address the complex challenges associated with advanced high speed interfaces. The design of such an equalizer traditionally involves large currents to provide the necessary gain at high data or frequency rates. Conventional equalizers include several amplifiers and other circuits for direct current compensation and to compensate for increased bandwidth and gain of the equalizer, which results in an increased lag time. Conventional linear equalizers, for example, compensate for gain by using a feedback zero to create an additional zero (frequency at which the amplifier gain begins to increase). These linear equalizers, however, also use several amplifiers and other circuits for direct current compensation.

### SUMMARY

According to some aspects of the disclosure, a receiver equalization circuit includes a first output transistor having a gate coupled to an input signal. The receiver equalization circuit may also include a second output transistor having a drain coupled to a drain of the first output transistor. The receiver equalization circuit may also include a resistor coupled between a gate and a drain of the second output transistor to provide a direct current (DC) bias to the gate of the second output transistor. The receiver equalization circuit may further include a feed-through capacitor coupled between the gate of the second output transistor and an input signal source. The feed-through capacitor feeds the input signal to the gate of the second output transistor when a frequency of the input signal is above a predetermined threshold. The feed-through capacitor and the resistor define a signal gain amplification point.

According to some aspects of the disclosure, a method within a receiver equalization circuit includes receiving an input signal at a gate of a first output transistor. A drain of the first output transistor is coupled to a drain of a second output transistor. The method may also include providing a direct current bias to the gate of the second output transistor by a resistor coupled between a gate and the drain of the second output transistor. The method may also include feeding the input signal through a capacitor to the gate of the second output transistor when a frequency of the input signal is above a predetermined threshold. The capacitor is coupled between the gate of the second output transistor and an input signal source. The capacitor and the resistor define a signal gain amplification point.

According to some aspects of the disclosure, a receiver equalization circuit includes a first output transistor having a gate coupled to an input signal. The receiver equalization circuit may also include a second output transistor having a drain coupled to a drain of the first output transistor. The receiver equalization circuit may also include means for providing a direct current bias to the gate of the second output transistor. The direct current bias providing means is coupled between a gate and a drain of the second output transistor. The receiver equalization circuit may also include means for feeding the input signal to the gate of the second output transistor when a frequency of the input signal is above a predetermined threshold. The feeding means is coupled between the gate of the second output transistor and an input signal source. The feeding means and the direct current bias providing means define a signal gain amplification point.

According to some aspects of the disclosure, a method within a receiver equalization circuit includes the step of receiving an input signal at a gate of a first output transistor. A drain of the first output transistor is coupled to a drain of a second output transistor. The method may also include the step of providing a direct current bias to the gate of the second output transistor by a resistor coupled between a gate and the drain of the second output transistor. The method may also include the step of feeding the input signal through a capacitor to the gate of the second output transistor when a frequency of the input signal is above a predetermined threshold. The capacitor is coupled between the gate of the second output transistor and an input signal source. The capacitor and the resistor define a signal gain amplification point.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings.

FIG. 1 is a block diagram illustrating communication layers according to a serial advanced technology attachment (SATA) specification for interconnecting a host device to a peripheral device.

FIG. 2 is a block diagram illustrating the host device and the peripheral device of FIG. 1, interconnected with interfaces including receiver equalization circuits according to some aspects of the disclosure.

FIG. 3 is an example of a single-ended receiver equalization circuit for implementing a receiver equalization technique according to some aspects of the disclosure.

FIG. 4 is an example of a differential receiver equalization circuit for implementing a receiver equalization technique according to some aspects of the disclosure.

FIG. 5 shows multiple frequency responses of a receiver equalization circuit according to some aspects of the disclosure.

FIG. 6 illustrates a method for implementing an equalization operation according to an aspect of the present disclosure.

FIG. 7 shows an exemplary wireless communication system in which an embodiment of the disclosure may be advantageously employed.

FIG. 8 is a block diagram illustrating a design workstation used for circuit, layout, and logic design of a semiconductor component according to one aspect of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

One aspect of the disclosure describes a receiver equalization technique for serial communication, which may conform to any number of serial interface protocols, such as Peripheral Component Interconnect (“PCT”), PCI Express, Serial Advanced Technology Attachment (“SATA”), and fiber channel among other serial interface protocols. For clarity, the receiver equalization technique is specifically described below with reference to a Serial Advanced Technology Attachment (“SATA”) specification.

One aspect of the disclosure includes a receiver equalization circuit that extends the gain, bandwidth, and the peaking ratio of a receiver. The peaking ratio is the difference between a direct current gain of the receiver equalization circuit and a high gain point (e.g., in dB) referred to as the peaking point of the receiver equalization circuit. For example if the direct current gain is 5 dB and the high gain point at some high frequency is 8 dB then the peaking ratio is 3 dB.

In some aspects of the disclosure, the receiver equalization circuit includes a first output transistor having a gate coupled to an input signal. The receiver equalization circuit also includes a second output transistor having a drain coupled to the drain of the first output transistor. The first and second output transistors provide an approximately 180 degree phase-shifted version of the input signal into a load of the receiver equalization circuit. A resistor of the receiver equalization circuit is coupled between a gate and the drain of the second output transistor. The resistor provides a direct current bias to the gate of the second output transistor. The receiver equalization circuit also includes a feed-through capacitor coupled between the gate of the second output transistor and a source (e.g., an input transistor) that supplies the input signal. The feed-through capacitor feeds an approximately 180 degree phase-shifted version of the input signal to the gate of the second output transistor when a frequency of the input signal is above a predetermined threshold. The feed-through capacitor and the resistor define a signal gain amplification point. This implementation extends a bandwidth of a serial interface receiver circuit.

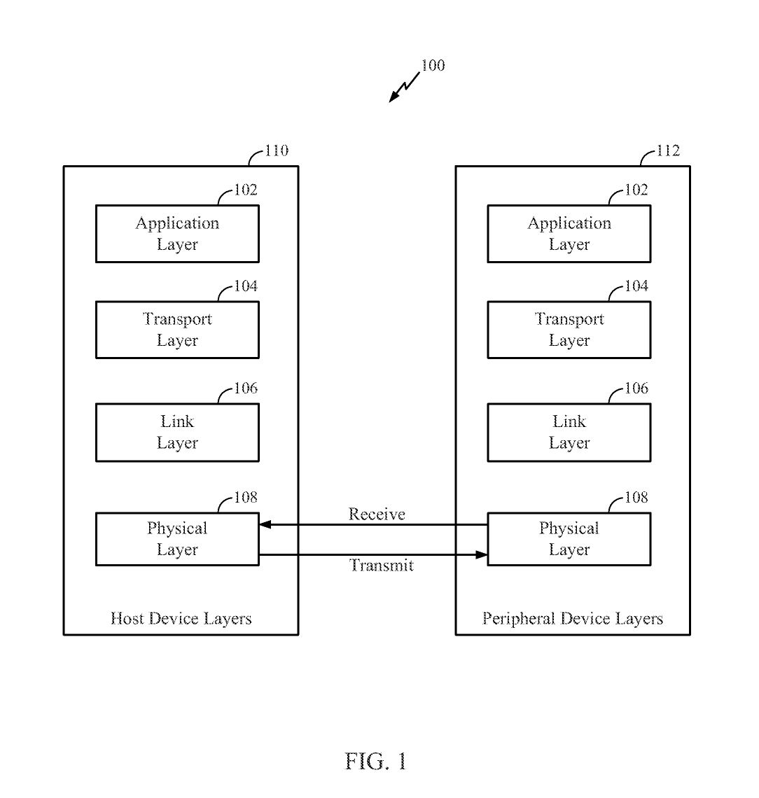

FIG. 1 is a block diagram of a set of communication layers according to a serial advanced technology attachment (SATA) specification for interconnecting a host device 110 to a peripheral device 112. The communication layers include a physical layer 108, a link layer 106, a transport layer 104, and an application layer 102. The set of communication layers at the of the host device 110 correspond to the set of communication layers at the peripheral device 112. The physical layer 108 performs conversions between digital and analog signals. For example, the physical layer 108 receives a digital signal from the link layer 106, converts the digital signal into an analog signal, and transmits the analog signal to the other device 110 and 112. In addition, the physical layer 108 also receives an analog signal from one of the devices 110 and 112, converts the analog signal to a digital signal, and transmits the digital signal to the link layer 106.

The link layer 106 encodes digital data received from the transport layer 104 and transmits the encoded data to the physical layer 108. In addition, the link layer 106 decodes digital data received from the physical layer 108 and transmits the decoded data to the transport layer 104. The transport layer 104 also constructs and deconstructs a frame information structure for the data according to a format defined in the SATA specification, for example. The application layer 102 generally controls a buffer memory and any direct memory access engines.

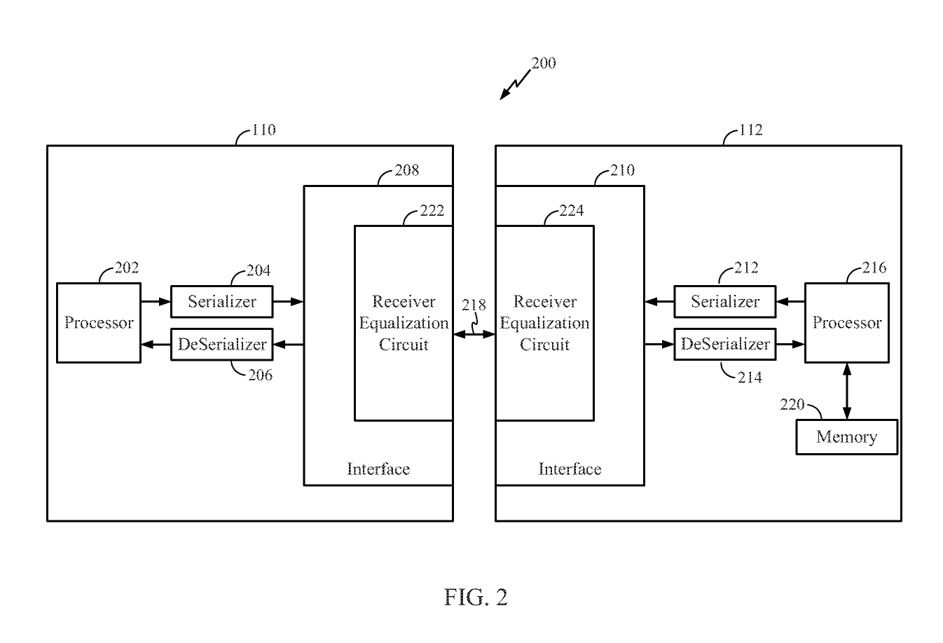

FIG. 2 is a block diagram 200 illustrating the host device 110 and the peripheral device 112 of FIG. 1, interconnected with SATA interfaces 208 and 210 including receiver equalization circuits 222 and 224 according to some aspects of the disclosure. The SATA interfaces 208, 210 may be integrated into a single device (i.e., the host device 110 or the peripheral device 112). Alternatively, the SATA interfaces 208, 210 may be independent but communicatively coupled to the peripheral device 112 and/or the host device 110, via a serial bus or interconnect. The interface 208 is coupled to or integrated within the host device 110 at one end and of an interconnect 218, and another interface 210 is coupled to or integrated within the peripheral device 112 at the other end of the interconnect 218.

The host device 110 includes a processor 202 communicating with a serializer 204 and a deserializer 206. Alternatively, the processor 202 can be independent but coupled to the host device 110. A communication associated with a host command is serialized and transmitted via the SATA interface 208 to the peripheral device 112. Similar to the host device 110, the peripheral device 112 also includes a processor 216 in communication with a deserializer 214 and a serializer 212. The processor 216 also stores data to and retrieves data from a memory 220. When a command from the processor 216 to retrieve data from the memory 220 is initiated, that data is serialized and transmitted via the SATA interface 210 to the host device 110.

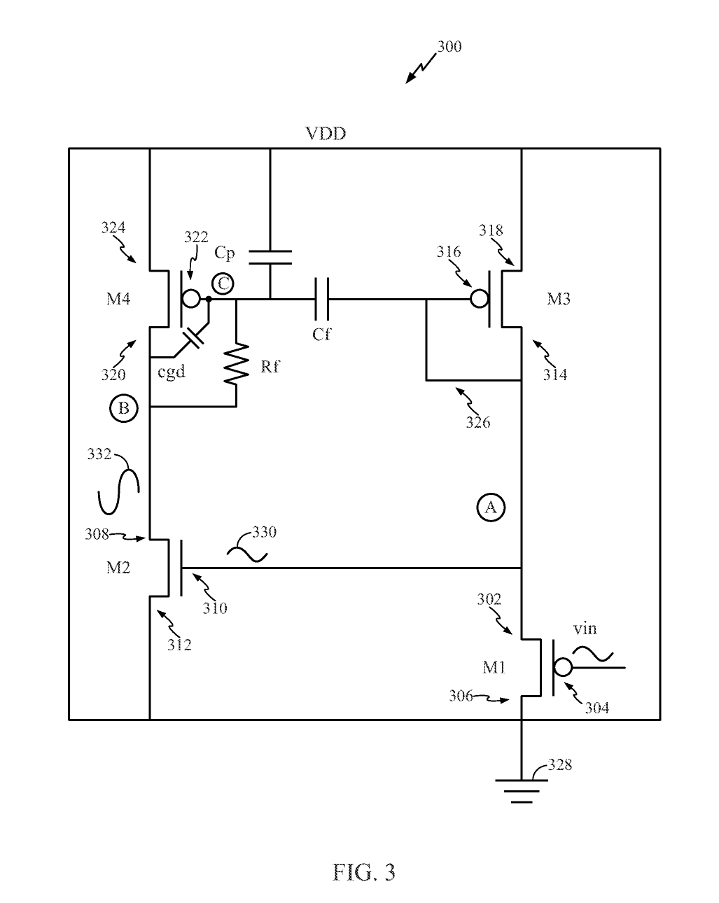

As previously noted, when signals propagate along the communication or transmission channel, the signals are subject to increasing losses that occur at higher and higher frequencies. In order to compensate for the channel loss an equalizer such as a single-ended receiver equalization circuit or a differential receiver equalization circuit may be adopted at the front end of a receiver to balance the channel loss. Accordingly, each interface 208 and 210 may include receiver equalization circuits 222 and 224, respectively, such as a single and/or a differential receiver equalization circuit. In some aspects of the disclosure, the receiver equalization circuits 222 and 224 may be independent but coupled to the interfaces 208 and 210, respectively, as further described in FIG. 3.

FIG. 3 is an example of a single-ended receiver equalization circuit 300 for implementing a receiver equalization technique according to one aspect of the disclosure. The single-ended receiver equalization circuit 300 includes a set of the transistors M1, M2, M3 and M4, with M1 being an input transistor and M2 and M4 being output transistors. In some aspects of the disclosure, the transistor M2 is a negative-channel metal-oxide semiconductor (NMOS) transistor while the transistors M1, M3 and M4 are positive-channel metal-oxide semiconductor (PMOS) transistors. Although each transistor is designated as a NMOS or PMOS transistor, the transistors can be interchanged from NMOS to PMOS, or vice versa, while conforming to the design of the single-ended receiver equalization circuit 300. The input transistor M1 receives an input signal Vin from a signal source (e.g., peripheral device) and provides the input signal to the transistors M2, M3 and M4. In some aspects of the disclosure, the input signal may be independent of the transistor M1. For example, the input signal Vin can be received from a capacitor circuit, a resistor divider circuit, an operation amplifier circuit, or the like. In some aspects of the disclosure, the input signal Vin is level-shifted at the transistor M1 or any other input circuit before the input signal is provided to the transistors M2, M3 and M4.

As shown in FIG. 3, the transistor M1 includes a source 302, a gate 304, and a drain 306. The transistor M2 includes a drain 308, a gate 310 and a source 312. The transistor M3 includes a drain 314, a gate 316 and a source 318. The transistor M4 includes a drain 320, a gate 322 and a source 324. The single-ended receiver equalization circuit 300 also includes a feedback resistor Rf, a feed-through capacitor Cf, and capacitances Cp and Cgd. Although the capacitances Cp and Cgd are illustrated as physical capacitors, they are parasitic capacitances that are accounted for in a design model of the single-ended receiver equalization circuit 300. Cp, however, can be implemented as a physical capacitor at a very low frequency (e.g., 200 MHz).

For explanatory purposes, FIG. 3 illustrates the parasitic capacitor Cgd as a physical capacitor. Representatively, the parasitic capacitor Cgd includes terminals coupled between position B, which is associated with the drains 308 and 320 of the transistors M2 and M4, and to the gate 322 of the transistor M4 at position C. When implemented physically, the terminals of the parasitic capacitor Cp are coupled between position C and VDD. The terminals of the feed-through capacitor Cf are coupled between position A, which is associated with the source 302 and drain 314 of the transistors M1 and M3, and to the gate 322 of the transistor M4 at position C. An interconnect 326 couples the drain 314 and source 302 of the transistors M3 and M1 at position A to a terminal of the feed-through capacitor Cf.

FIG. 3 also illustrates that the sources 324 and 318 of the transistors M4 and M3 are coupled to a supply voltage VDD. The source 312 and drain 306 of the transistors M2 and M1 are coupled to a ground terminal 328. The drains 308 and 320 of the transistors M2 and M4 are coupled to each other at position B between the transistors M2 and M4. The terminals of the feedback resistor Rf are coupled between position B, which is associated with the drains 308 and 320, and to the gate 322 of the transistor M4 at position C. The feedback resistor Rf provides a DC bias to the gate 322 of the transistor M4. In some aspects of the disclosure, transistors M1 and M3 set the gate or bias voltage of the transistor M2. Representatively, the transistor M3 operates as resistor biasing circuit to provide a resistance and the transistor M1 operates as a current to set the gate voltage of the transistor M2. The transistor M3 is also used as an interconnect to feed the input signal 330 to the capacitor Cf to feed an alternating current (AC) bias or a direct current (DC) bias to the capacitor Cf.

In some aspects of the disclosure, the input signal Vin is level shifted to a threshold signal Vth, at position A, where the threshold signal Vth is above the input signal Vin that is received at the gate 304 of the transistor M1. In this configuration, the threshold signal Vth provides a direct current bias for the transistor M2. Alternatively, the input signal Vin may not be level shifted. Moreover, the input signal Vin may be independent of the transistor M1 and may be provided through a capacitor circuit, a resistor divider circuit, an operation amplifier circuit or the like.

An input signal 330 at the gate 310 of the transistor M2 is in phase with the input signal received at the gate 304 of the transistor M1. An output signal 332 at the drain of the transistor M2, however, is phase shifted by approximately 180 degrees across the transistor M2. As shown in FIG. 3, the approximately 180 degree phase-shifted output signal 332 is provided to a load as seen from the output of the transistor M2. The transistors M2 and M4 provide the approximately 180 degree phase-shifted output signal 332. The approximately 180 degree phase-shifted output signal 332 is applied to determine the gain at the output of the transistor M2.

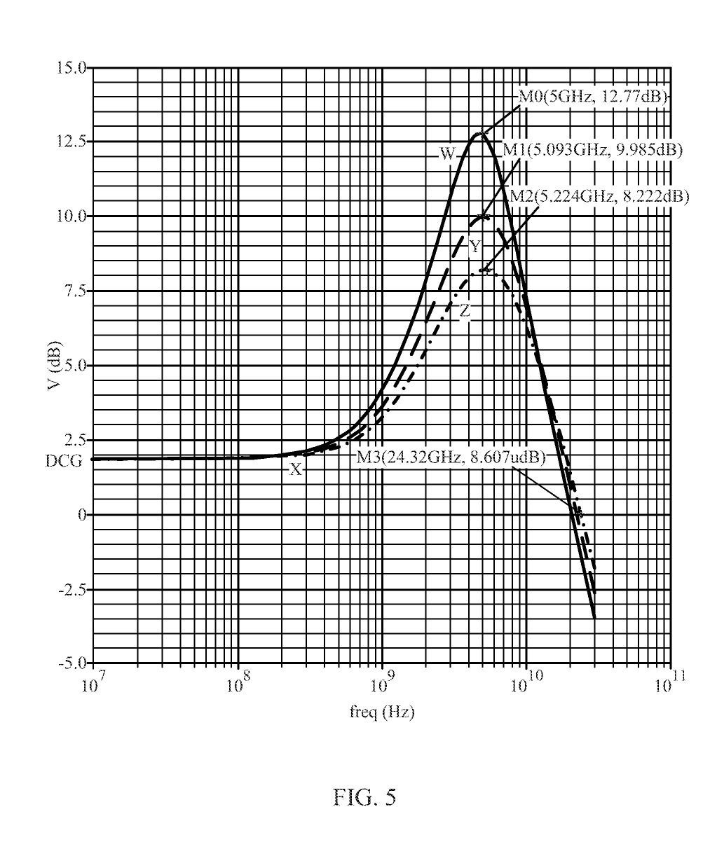

The single-ended receiver equalization circuit 300 of FIG. 3 defines a zero or a signal gain amplification point (e.g., approximately 0.5 GHz at point X, illustrated in FIG. 5) at its frequency response, which is a frequency at which the amplifier gain begins to increase. In general, the frequency response of the transmission channel begins to drop dramatically at a drop-off point or frequency. In one aspect, the single-ended receiver equalization circuit 300 applies a gain starting at the signal gain amplification point to compensate for the dramatic drop in the frequency response. In this configuration, the signal gain amplification point is designed to correspond to the frequency at the drop-off point. In particular, the signal gain amplification point provides a starting position at which the gain of the frequency response of the receiver equalization circuit starts to rise. The signal gain amplification point is defined by the feed-through capacitor Cf in conjunction with the feedback resistor Rf. In some aspects of the disclosure, the feedback resistor Rf may be a variable resistor to vary the signal gain amplification point. For example, the feedback resistor Rf can be varied or adjusted to extend or reduce the signal gain amplification point. In some aspects of the disclosure, the parasitic capacitance Cgd between the gate and the drain of the output transistor M4 is accounted for in the design model of the single-ended receiver equalization circuit 300 to further define the signal gain amplification point.

In operation, an input signal from a peripheral device Vin (e.g., streaming data or bits from a hard disk) is received at the gate 304 of the transistor M1. Under direct current (DC) conditions (i.e., at low frequencies, e.g., frequencies less than or equal to a frequency of approximately 0.5 giga hertz (GHz) or less at point X, illustrated in FIG. 5) the feed-through capacitor Cf operates as an open circuit. As a result, the input signal is channeled through the feedback resistor Rf to the gate 322 of the transistor M4, and not through the feed-through capacitor Cf. Therefore, a direct current input voltage across the feedback resistor Rf is fed to the gate 322 of M4. Similarly, at low frequencies (or under direct current conditions) the input signal path is also channeled away from the parasitic capacitance Cgd because the parasitic capacitance Cgd also operates as an open circuit. Because approximately all of the signal is channeled through the feedback resistor Rf at low frequencies, the transistor M4 appears as a small resistive load when seen from the output of the transistor M2. This resistive load feature of the transistor M4 is adequate under DC conditions because the transmission channel does not attenuate signals at lower frequencies.

Under these conditions, a direct current gain (e.g., DCG illustrated in FIG. 5) as seen from the output of the transistor M2 is a fixed low value (e.g., 1/gₘ, where gₘ is a transconductance ratio corresponding to a current output associated with the input signal or voltage). Therefore, the direct current gain of the single-ended receiver equalization circuit 300 is defined by the gain at M2 (i.e., gₘ₂) multiplied by the gain of M4, which is given by the resistive load at M4 (i.e., g_{m2*1}/gₘ₄). The direct current gain (DCG) may be a fixed or constant value over a range of low frequencies starting from a low frequency (e.g., 10⁷ Hz as illustrated in FIG. 5) to some increased frequency point (e.g., approximately 0.5 GHz at point X, illustrated in FIG. 5). The increased frequency point corresponds to the signal gain amplification point described above and illustrated by position X in FIG. 5.

As the frequency of the input signal Vin increases above the DC level, however, the single-ended receiver equalization circuit 300 may be subject to a shunt peaking effect. The shunt peaking effect is caused by a low resistance connection between two points in the single-ended receiver equalization circuit 300 that form an alternative path for a portion of the approximately 180 degrees phase shifted output signal 332. This feature results in part because, as the frequency of the phase shifted output signal 332 increases, the parasitic capacitance Cgd starts to operate as a short circuit, creating an accessible path for the input signal. As a result, the transistor M4 starts to appear as a larger resistive load or resistor as seen from the output of the transistor M2. Under these conditions, the gain associated with the transistors M2 and M4 is determined by the gain at the transistor M2 (i.e., gₘ₂) multiplied by the increased resistance, R_{increased} at M4. As a result, the gain under these conditions is increased in comparison to the gain at a purely direct current or lower frequency conditions.

As the frequencies of the input signal continues to increase, beyond some increased frequency value, substantially all of the 180 degrees phase shifted output signal 332 is passed through the parasitic capacitance Cgd and then grounded by the parasitic capacitance Cp. As the result, the feedback resistor Rf is substantially bypassed. Under these conditions, the transistor M4 no longer toggles and the gain of the single-ended receiver equalization circuit 300 is substantially reduced. Because the gain at the transistor M2 is substantially reduced, the peaking ratio, which is the difference between the DC gain (e.g., DCG illustrated in FIG. 5) and a high point or peaking point of the receiver (e.g., M2 illustrated in FIG. 5), is also substantially reduced. Moreover, the bandwidth of the single-ended receiver equalization circuit 300 is effectively reduced because under these conditions, the transistor M4 is not toggled and these higher frequency signals are essentially grounded by the parasitic capacitance Cp.

To extend the gain, bandwidth and peaking ratio, some aspects of the disclosure implement the feed-through capacitor Cf, which is coupled between the gate 322 of the output transistor M4 and the source 302 of the transistor M1. An interconnect 326 couples a terminal of the feed-through capacitor Cf at the gate of the transistor M3 to the source 302 of the transistor M1 at position A. The feed-through capacitor Cf feeds a 180 degrees phase shifted output signal to the gate 322 of the transistor M4 when a frequency of the input signal meets or is above a predetermined threshold value. The bandwidth is extended because higher frequency signals are accommodated by feeding the high frequency signals through the feed-through capacitor Cf. These higher frequency signals received by the single-ended receiver equalization circuit 300 that meet or exceed a threshold value can now be routed through the feed-through capacitor Cf to toggle the transistor M4. Effectively, the feed-through capacitor Cf is introduced to counter the effect of the parasitic capacitance Cgd by accommodating the higher frequency signals that meet or exceed a threshold value through the feed-through capacitor Cf. As previously noted, these higher frequency signals were otherwise routed through the parasitic capacitance Cgd where they are grounded by the parasitic capacitance Cp. Therefore, the feed-through capacitor Cf implementation extends the bandwidth of the single-ended receiver equalization circuit 300.

Moreover, feeding the approximately 180 degrees phase shifted output signal to the gate 322 of the transistor M4 results in the transistors M2 and M4 operating together, with both transistors contributing to the output gain of the single-ended receiver equalization circuit 300. As a result, the gain of the single-ended receiver equalization circuit 300 is also extended because the total output gain is effectively doubled. In this configuration, the total output gain is based on the gain seen at both the transistors M2 and M4 instead of the single gain at transistor M2. The boost in the gain of the single-ended receiver equalization circuit 300 is independent of any additional stage amplifiers. In addition, the DC gain is unaffected because the feed-through capacitor Cf blocks any DC signals.

As previously indicated, the peaking ratio is the difference between a direct current gain (e.g., DCG illustrated in FIG. 5) of the receiver equalization circuit and high gain point (e.g., M2 illustrated in FIG. 5) referred to as the peaking point of the receiver equalization circuit. As noted above, the feed-through capacitance Cf couples the input signal Vin at position A to the gate 322 of the transistor M4, which effectively complements the peaking gain seen at the output of the transistor M2. This technique allows for an improved or increased gain than would normally be seen at the output of the transistor M2. The increased gain correlates to an increased high gain point (e.g., M0 illustrated in FIG. 5), which results in an increase of the peaking ratio of the single-ended receiver equalization circuit 300.

The equalization technique described according to one aspect of the disclosure includes a self-biasing circuit that reduces current, reduces power consumption, extends the bandwidth of the amplifiers, and reduces the parasitic elements such as parasitic capacitances associated with the receiver equalization circuit design. The extended peaking ratio, bandwidth, and gain are achieved without an additional gain stage. As a result, the overall size and power consumption of the single-ended receiver equalization circuit 300 is reduced.

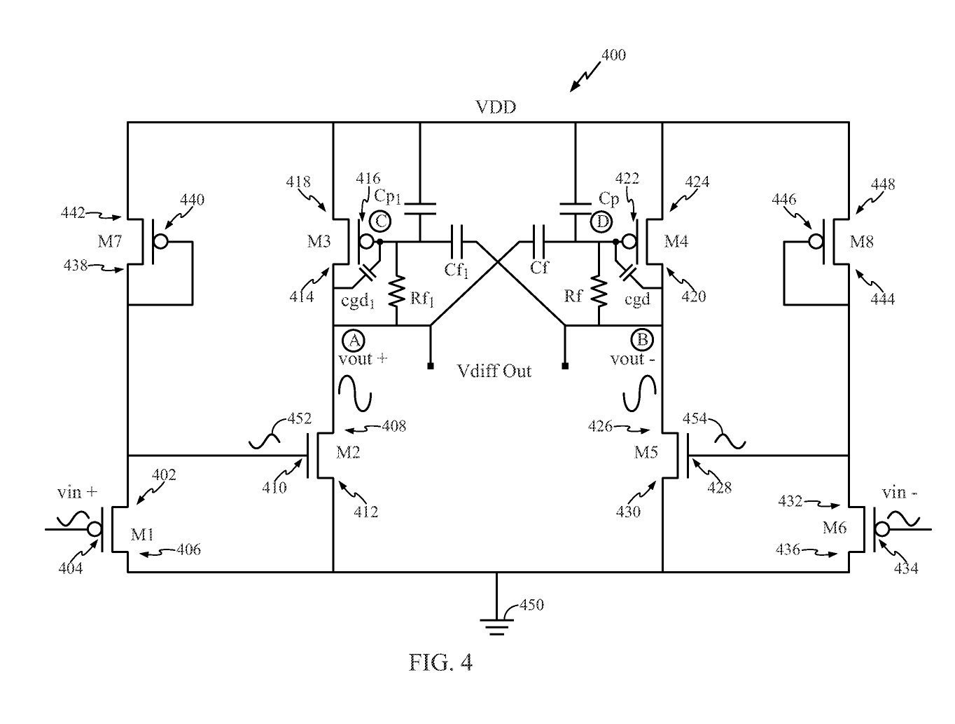

FIG. 4 is an example of a differential receiver equalization circuit for implementing a receiver equalization technique according to some aspects of the disclosure. The operation of the differential receiver equalization circuit 400 is essentially the same as described for the single-ended receiver equalization circuit 300. The difference between the circuits is that differential receiver equalization circuit 400 includes a differential pair of inputs and outputs in which the feed-through signals for the feed-through capacitors Cf1 and Cf are taken from output nodes or positions A and B. Therefore, instead of routing a signal back to a transistor as in the single-ended receiver equalization circuit 300, a first output signal on a positive input side is amplified and routed to the feed-through capacitor Cf. Similarly, on the negative input side, a second output signal is amplified and routed to the feed-through capacitor Cf1. This differential structure yields two signals on each side of the feed-through capacitors Cf1 and Cf that are substantially 180 degrees out of phase.

The differential receiver equalization circuit 400 includes transistors M1, M2, M3, M4, M5, M6, M7 and M5, with M1 and M6 being the input transistors and transistors M2, M3, M4 and M5 being the output transistors. In some aspects of the disclosure, transistors M1, M3, M4, M6, M7 and M8 are PMOS transistors while transistors M2 and M5 are NMOS transistors. Although each transistor is designated as a NMOS or PMOS transistor, the transistors can be interchanged from NMOS to PMOS or vice versa while conforming to the design of the differential receiver equalization circuit 400.

As shown in FIG. 4, the transistor M1 includes a drain 402, a gate 404 and a source 406. The transistor M2 includes a drain 408, a gate 410 and a source 412. The transistor M3 includes a drain 414, a gate 416 and a source 418. The transistor M4 includes a drain 420, a gate 422 and a source 424. The transistor M5 includes a drain 426, a gate 428 and a source 430. The transistor M6 includes a drain 436, a gate 434 and a source 432. The transistor M7 includes a drain 438, a gate 440 and a source 442. The transistor M8 includes a drain 444, a gate 446 and a source 448. The input transistors M1 and M6 may be configured to receive differential input signals. For example, the transistor M1 receives a positive differential input (e.g., positive input signal Vin+) and the transistor M6 may be configured to receive a negative differential input (e.g., negative input signal Vin−). In some aspects of the disclosure, the differential input signals may be independent of the transistors M1 and M6. For example, the differential input signals can be received from capacitor circuits, resistor divider circuits, operation amplifier circuits, or the like. In some aspects of the disclosure, the differential input signals are level-shifted at the transistors M1 and M6.

The differential receiver equalization circuit 400 also includes feedback resistors Rf and Rf1, feed-through capacitors Cf and Cf₁, capacitors Cp and Cp1 and capacitors Cgd and Cgd1. Although the capacitors Cp and Cp1, and, Cgd and Cgd1 are illustrated as physical capacitors, they may be parasitic capacitances that are accounted for in a design model of the differential receiver equalization circuit 400. The parasitic capacitors Cgd1 and Cgd are illustrated as a physical capacitors having terminals coupled between positions A and C and positions B and D, respectively. When implemented physically, the terminals of the parasitic capacitors Cp1 and Cp are coupled between positions C, D, and VDD, respectively. The terminals of the feed-through capacitors Cf1 and Cf are coupled between positions B and C and positions A and D, respectively. The feedback resistors Rf1 and Rf are coupled between positions A and C and positions B and D, respectively. The feedback resistors Rf1 and Rf provide a direct current bias to the gates 416 and 422 of the transistors M3 and M4, respectively.

As further illustrated in FIG. 4, the sources 442, 418, 424 and 448 of the transistors M7, M3, M4, and M8 are coupled to a supply voltage VDD. The sources 406, 412, 430, and drain 436 of the transistors M1, M2, M5 and M6 are coupled to a ground terminal 450. The drains 408, 414 of the transistors M2 and M3 are coupled to each other at position A. Similarly, the drains 426 and 420 of the transistors M5 and M4 are coupled to each other at position B.

Representatively, the transistors M7 and M8 operate as resistor biasing circuits to provide a resistance and the transistors M1 and M6 operate as a current to set the gate voltage of the transistors M2 and M5, respectively. The transistors M7 and M8 are also used as interconnects to feed a signal from the output transistors M3 and M4 to the gates of the transistors M2 and M5, respectively.

In some aspects of the disclosure, the differential input signals Vin+ and Vin− are in phase with the signals 452 and 454 received at the gates 410 and 428 of the transistors M2 and M5, respectively. Conversely, the output signals Vout+ and Vout− at positions A and B, corresponding to the outputs of the transistors M2 and M5, respectively, are phase shifted by approximately 180 degrees with respect to the input signals Vin+ and Vin−, respectively. The approximately 180 degree phase-shifted output signals Vout+ and Vout− are implemented to determine the gain at the outputs of the transistors M2 and M5. In some aspects of the disclosure, the transistors M1 and M7 set the gate or bias voltage of the transistor M2. Similarly, the transistors M6 and M8 set the gate or bias voltage of the transistor M5.

Similar to the single-ended receiver equalization circuit 300 of FIG. 3, the signal gain amplification point (e.g., approximately 0.5 GHz at point X, illustrated in FIG. 5) for either side of the differential receiver equalization circuit 400 of FIG. 4 can be defined by the feedback resistors Rf1 and Rf in conjunction with the feed-through capacitors Cf1 and Cf, respectively. In some aspects of the disclosure, the parasitic capacitances Cgd1 and Cgd also contribute to the definition of the signal gain amplification point. The feed-through capacitors Cf1 and Cf and the resistors Rf1 and Rf define the signal gain amplification point. In some aspects of the disclosure, the resistors Rf1 and Rf may be variable resistors to vary the signal gain amplification point. For example, the feedback resistors Rf1 and Rf can be varied or adjusted to extend the signal gain amplification point.

As further illustrated in FIG. 4, under direct current (DC) conditions (i.e., at low frequencies, e.g., frequencies less than or equal to a frequency of approximately 0.5 giga hertz (GHz) or less at point X, illustrated in FIG. 5) the feed-through capacitors Cf1 and Cf operate as an open circuit. As a result, the differential input signals are channeled through the feedback resistors Rf1 and Rf and not through the feed-through capacitors Cf1 and Cf. In other words, the DC signals are fed through the resistors Rf1 and Rf to the gates 416 and 422, respectively. Similarly, at low frequencies the parasitic capacitances Cgd1 and Cgd operate as open circuits. As a result, the transistors M3 and M4 appear to be small resistive loads from the outputs of the transistors M2 and M5, respectively. Under these conditions, a direct current gain (e.g., DCG illustrated in FIG. 5), as seen from the output of the transistors M2 and M5, is a fixed low value (e.g., 1/gₘ, where gₘ is a transconductance ratio corresponding to a current output associated with the input signal or voltage). Similar to the illustration of FIG. 3, the direct current gain is a fixed or constant value over a range of low frequencies starting from a low frequency point (e.g., 10⁷ Hz as illustrated in FIG. 5) to some increased frequency point (e.g., approximately 0.5 GHz at point X, illustrated in FIG. 5). The increased frequency point corresponds to the signal gain amplification point described above.

As the frequency increases above the DC level, the parasitic capacitance Cgd and Cgd starts to operate as a short circuit and create an accessible signal path through the capacitances Cgd1 and Cgd. As a result, the transistors M3 and M4 start to appear as a larger resistors or resistive loads. Under these conditions, the gain of the differential receiver equalization circuit 400 is given by the gain associated with transistors M2 and M3 or the gain associated with the transistors M4 and M5. The gain of transistors M2 and M3 is the product of the gain at the transistor M2 and the resistive load across M3. Similarly, the gain of transistors M4 and M5 is the product of the gain at the transistor M5 and the resistive load across M4. As a result, the gain under these conditions is increased in comparison to the gain at a purely direct current or lower frequency condition.

Similar to the illustration in FIG. 3, as the frequencies of the differential input signals continue to increase, beyond some increased frequency value, substantially all of the input signal is passed through the parasitic capacitance Cgd1 and Cgd and then grounded by the parasitic capacitance Cp1 and Cp. Under these conditions, the transistors M3 and M4 are not toggled and the gain of the differential receiver equalization circuit 400 is substantially reduced. As a result, the peaking ratio is also substantially reduced.

As shown in FIG. 4, the feed-through capacitors Cf1 and Cf extend the gain, bandwidth, and peaking ratio of the differential receiver equalization circuit 400. Unlike the single-ended receiver equalization circuit 300, the feed-through signals for the feed-through capacitors Cf1 and Cf of the differential receiver equalization circuit 400 are received at the output nodes or positions A and B. Therefore, instead of routing a signal back to a transistor as in the single-ended receiver equalization circuit 300, the positive differential signal of FIG. 4 is amplified and routed to the feed-through capacitor Cf. Similarly, the negative differential input signal is amplified and routed to the feed-through capacitor Cf1. This differential structure yields two signals on each side of the feed-through capacitors Cf1 and Cf that are substantially 180 degrees out of phase.

The feed-through capacitors Cf1 and Cf feed the 180 degree phase shifted output signal to gates 416 and 422 of the transistors M3 and M4, respectively, when a frequency of the input signal meets or is above a predetermined threshold value. As noted with respect to the single-ended receiver equalization circuit 300, this feature results in an extension of the bandwidth of the receiver equalization circuit 400. Effectively, Cf1 and Cf are introduced to counter the effect of the parasitic capacitance Cgd1 and Cgd. As shown in FIG. 4, the feed-through capacitors Cf1 and Cf accommodate the higher frequency signals that meet or exceed the threshold value through the feed-through capacitors Cf1 and Cf, instead of being grounded by the capacitances Cp1 and Cp.

As further illustrated in FIG. 4, feeding the 180 degrees phase shifted output signals Vout+ and Vout− to the gates 416 and 422 causes the transistors M3 and M4 to operate together with the transistors M2 and M5, respectively. In addition to the gain associated with transistors M2 and M5, the transistors M3 and M4 also contribute to the output gain of the differential receiver equalization circuit 400. As a result, the gain of differential receiver equalization circuit 400 is extended or increased because the total output gain is based on the gain seen at both the transistors M2 and M5 and the transistors M3 and M4, respectively. Therefore, instead of realizing gains on only the transistors M2 and M5, the transistors M3 and M4 become part of the gain of the differential receiver equalization circuit 400. The boost or increase in the gain of the differential receiver equalization circuit 400 is independent of any additional stage amplifiers. Moreover, the increased gain correlates to an increased high gain point (e.g., M0 illustrated in FIG. 5), which results in an increase of the peaking ratio of the differential receiver equalization circuit 400. The values of the feedback resistors Rf1 and Rf and the feed-through capacitors Cf1 and Cf are used to set the peaking ratio and a peaking frequency associated with the high gain point. The bandwidth is also extended because the higher frequency signals are accommodated by feeding the high frequency signals through the feed-through capacitors Cf1 and Cf. The DC gain (e.g., DCG illustrated in FIG. 5) is unaffected because the feed-through capacitors Cf1 and Cf block any DC signals.

For illustrative purposes, FIG. 5 shows multiple frequency responses of a receiver equalization circuit according to some aspects of the disclosure. The x-axis represents the frequency in Hertz (Hz) and the y-axis represents a gain of the receiver equalization circuit. Referring to FIG. 5, the frequency curves W, Y and Z include a signal gain amplification point relative to position X at which each of the frequency curves W, Y and Z begin to rise. This rise coincides with an increase in the gain of the receiver equalization circuit above a direct current gain. For example, the frequencies less than or equal to a frequency of approximately 0.5 giga hertz (GHz) or less at point X are direct current frequencies. These direct current frequencies correspond to a fixed receiver equalization circuit gain of approximately 2 dB.

As the frequency of the input signal continue to increase and the gain of the receiver equalization circuit correspondingly increases, the curves W, Y and Z continue to rise up to high point or peaking point M0, M1 and M2, respectively. The high points M0, M1 and M2 correspond to a peaking point gain of 12.77 dB, 9.985 dB and 8.222 dB, respectively, and to peaking frequencies 5 GHz, 5.093 GHz and 5.224 GHz, respectively. The peaking ratio of each of the frequency curves W, Y and Z is respectively 10.77 dB, 7.985 dB and 6.222 dB as given by the difference between the peaking point gain and the direct current gain. The peaking point and the signal gain amplification point can be defined by the values of the feedback resistors Rf and/or Rf1, the feed-through capacitors Cf and, or Cf1 and the parasitic capacitances of the single-ended receiver equalization circuit 300 and the differential receiver equalization circuit 400 shown in FIG. 4. Position M3 illustrates a substantial drop in gain due to a shunting effect, for example.

The equalization technique described herein includes a self-biasing circuit that reduces the desire for multiple amplifiers, reduces current, extends the bandwidth of the amplifiers and reduces the parasitic elements such as parasitic capacitances associated with the equalization circuit design. The extended peaking ratio, bandwidth and gain are achieved without an additional gain stage. As a result, the overall size and power consumption of the receiver equalization circuit is reduced.

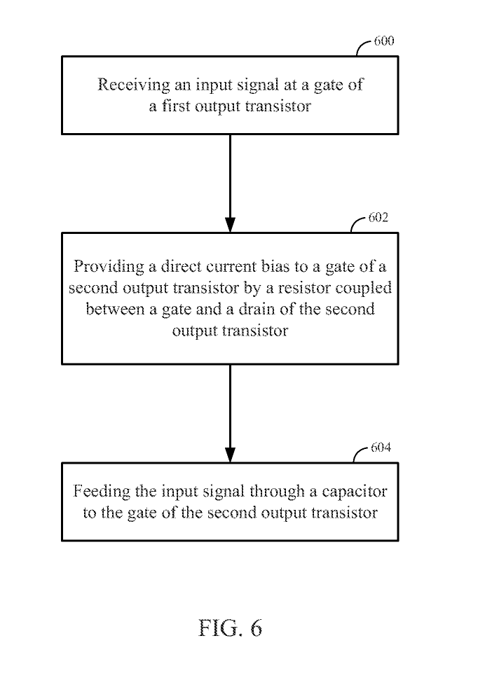

FIG. 6 illustrates a method for implementing an equalization operation according to an aspect of the present disclosure. The method includes receiving an input signal at a gate of a first output transistor at block 600. A drain of the first output transistor is coupled to a drain of a second output transistor. For example, as shown in FIG. 3, during operation an input signal 330 is received at the gate 310 of the transistor M2. At block 602, the method includes providing a direct current bias to the gate of the second output transistor by a resistor coupled between a gate and a drain of the second output transistor. For example, as shown in FIG. 3, the resistor Rf coupled between the gate 322 and the drain 320 of the transistor M4 provides direct current bias to the gate of M4. At block 604, the method includes feeding the input signal through a capacitor to the gate of the second output transistor when a frequency of the input signal is above a predetermined threshold. The capacitor is coupled between the gate of the second output transistor and an input signal source, where the capacitor and the resistor define a signal gain amplification point. For example, as shown in FIG. 3, the capacitor Cf feeds a signal to the gate 322 of the transistor M4 when a frequency of the input signal is above a predetermined threshold.

In one configuration, the apparatus includes means for providing a direct current bias to the gate of the second output transistor. In one aspect of the disclosure, the direct current bias providing means may be the resistor Rf and/or the resistor Rf1 configured to perform the functions recited by the direct current bias providing means. The apparatus may also include means for feeding the input signal to the gate of the second output transistor when a frequency of the input signal is above a predetermined threshold. In one aspect of the disclosure, the feeding means may be the capacitor Cf and/or the capacitor Cf1 configured to perform the functions recited by the feeding means, for example, as shown in FIGS. 3 and 4.

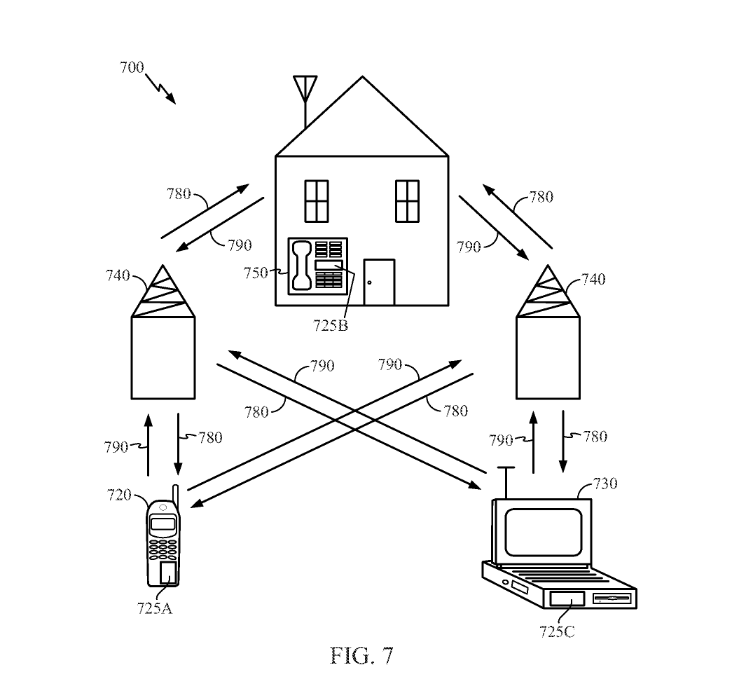

FIG. 7 shows an exemplary wireless communication system in which an embodiment of the disclosure may be advantageously employed. For purposes of illustration, FIG. 7 shows three remote units 720, 730, and 750 and two base stations 740. It will be recognized that wireless communication systems may have many more remote units and base stations. Remote units 720, 730, and 750 include receiver equalization circuits 725A, 725B, 725C. FIG. 7 shows forward link signals 780 from the base stations 740 and the remote units 720, 730, and 750 and reverse link signals 790 from the remote units 720, 730, and 750 to base stations 740.

In FIG. 7, the remote unit 720 is shown as a mobile telephone, remote unit 730 is shown as a portable computer, and remote unit 750 is shown as a fixed location remote unit in a wireless local loop system. For example, the remote units may be cell phones, hand-held personal communication systems (PCS) units, a set top box, a music player, a video player, an entertainment unit, a navigation device, portable data units, such as personal data assistants, or fixed location data units such as meter reading equipment. Although FIG. 7 illustrates remote units, which may employ a receiver equalization circuit 725A, 725B, 725C according to the teachings of the disclosure, the disclosure is not limited to these exemplary illustrated units. For instance, a receiver equalization circuit according to aspects of the present disclosure may be suitably employed in any device.

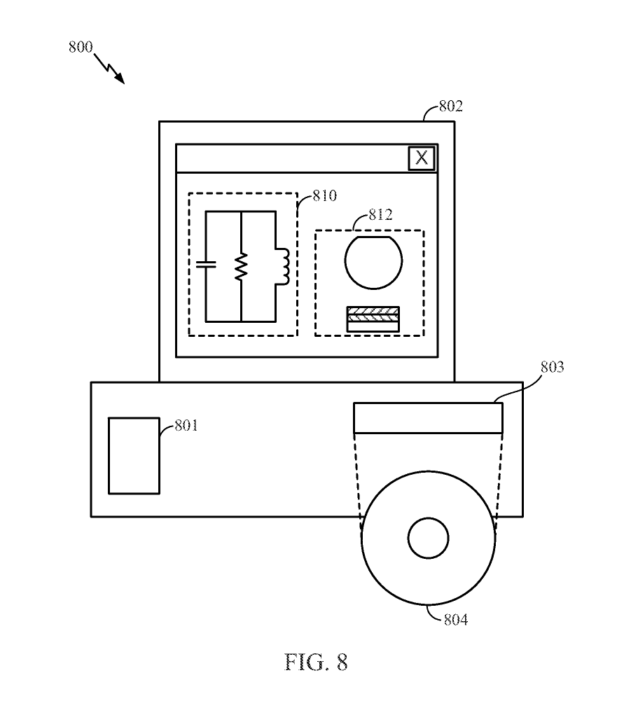

FIG. 8 is a block diagram illustrating a design workstation used for circuit, layout, and logic design of a semiconductor component, such as the receiver equalization circuit disclosed above. A design workstation 800 includes a hard disk 801 containing operating system software, support files, and design software such as Cadence or OrCAD. The design workstation 800 also includes a display 802 to facilitate design of a circuit 810 or a semiconductor component 812 such as a receiver equalization circuit. A storage medium 804 is provided for tangibly storing the circuit design 810 or the semiconductor component 812. The circuit design 810 or the semiconductor component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit design 810 or the semiconductor component 812 by decreasing the number of processes for designing semiconductor wafers.

Although specific circuitry has been set forth, it will be appreciated by those skilled in the art that not all of the disclosed circuitry is required to practice the disclosed embodiments. Moreover, certain well known circuits have not been described, to maintain focus on the disclosure.

The methodologies described herein may be implemented by various means depending upon the application. For example, these methodologies may be implemented in hardware, firmware, software, or any combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein, Any machine or computer readable medium tangibly embodying instructions may be used in implementing the methodologies described herein. For example, software code may be stored in a memory and executed by a processor. When executed by the processor, the executing software code generates the operational environment that implements the various methodologies and functionalities of the different aspects of the teachings presented herein. Memory may be implemented within the processor or external to the processor. As used herein, the term “memory” refers to any type of long term, short term, volatile, nonvolatile, or other memory and is not to be limited to any particular type of memory or number of memories, or type of media upon which memory is stored.

The machine or computer readable medium that stores the software code defining the methodologies and functions described herein includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer. As used herein, disk and/or disc includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present teachings and their advantages have been described in detail, it should be understood that various changes, substitutions and alterations can be made herein without departing from the technology of the teachings as defined by the appended claims. Moreover, the scope of the present application is not intended to be limited to the particular aspects of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding aspects described herein may be utilized according to the present teachings. Accordingly, the appended claims are intended to include within their scope such processes, machines, manufacture, compositions of matter, means, methods, or steps.

What is claimed is:

1. A receiver equalization circuit, comprising:
a first output transistor having a gate coupled to an input signal;
a second output transistor having a drain coupled to a drain of the first output transistor;
a resistor coupled between a gate and a drain of the second output transistor operable to provide a direct current (DC) bias to the gate of the second output transistor; and
a feed-through capacitor coupled between the gate of the second output transistor and an input signal source, the feed-through capacitor being operable to feed the input signal to the gate of the second output transistor when a frequency of the input signal is above a predetermined threshold, the feed-through capacitor and the resistor operable to define a signal gain amplification point.

2. The receiver equalization circuit of claim 1, further comprising capacitance between the gate and the drain of the second output transistor to further define the signal gain amplification point.

3. The receiver equalization circuit of claim 1, in which the first and second output transistors are operable to provide an approximately 180 degree phase-shifted version of the input signal into a load of the receiver equalization circuit.

4. The receiver equalization circuit of claim 1, in which a value of the feed-though capacitor and a value of the resistor define a peaking ratio and a peaking frequency of the receiver equalization circuit.

5. The receiver equalization circuit of claim 1, in which the feed-through capacitor is further operable to feed an approximately 180 degree phase-shifted version of the input signal to the gate of the second output transistor when a frequency of the input signal is above a predetermined threshold.

6. The receiver equalization circuit of claim 1, integrated into at least one of a mobile phone, a set top box, a music player, a video player, an entertainment unit, a navigation device, a computer, a hand-held personal communication systems (PCS) unit, a portable data unit, and a fixed location data unit.

7. A method within a receiver equalization circuit, comprising:
receiving an input signal at a gate of a first output transistor, a drain of the first output transistor being coupled to a drain of a second output transistor;
providing a direct current bias to the gate of the second output transistor by a resistor coupled between a gate and the drain of the second output transistor; and
feeding the input signal through a capacitor to the gate of the second output transistor when a frequency of the input signal is above a predetermined threshold, the capacitor being coupled between the gate of the second output transistor and an input signal source, the capacitor and the resistor operable to define a signal gain amplification point.

8. The method of claim 7, further comprising defining the signal gain amplification point based on a capacitance between the gate and the drain of the second output transistor.

9. The method of claim 7, further comprising providing an approximately 180 degree phase-shifted version of the input signal into a load of the receiver equalization circuit.

10. The method of claim 7, further comprising defining a peaking ratio and a peaking frequency of the receiver equalization circuit based on a value of the feed-though capacitor and a value of the resistor.

11. The method of claim 7, further comprising feeding, by the feed-through capacitor, an approximately 180 degree phase-shifted version of the input signal to the gate of the second output transistor when a frequency of the input signal is above a predetermined threshold.

12. The method of claim 7, further comprising integrating the receiver equalization circuit into at least one of a mobile phone, a set top box, a music player, a video player, an entertainment unit, a navigation device, a computer, a hand-held personal communication systems (PCS) unit, a portable data unit, and a fixed location data unit.

13. A receiver equalization circuit, comprising:
a first output transistor having a gate coupled to an input signal;
a second output transistor having a drain coupled to a drain of the first output transistor;
means for providing a direct current bias to the gate of the second output transistor, the direct current bias providing means coupled between a gate and a drain of the second output transistor; and
means for feeding the input signal to the gate of the second output transistor when a frequency of the input signal is above a predetermined threshold, the feeding means coupled between the gate of the second output transistor and an input signal source, the feeding means and the direct current bias providing means operable to define a signal gain amplification point.

14. The receiver equalization circuit of claim 13, integrated into at least one of a mobile phone, a set top box, a music player, a video player, an entertainment unit, a navigation device, a computer, a hand-held personal communication systems (PCS) unit, a portable data unit, and a fixed location data unit.

15. A method within a receiver equalization circuit, comprising the steps of:
receiving an input signal at a gate of a first output transistor, a drain of the first output transistor coupled to a drain of a second output transistor;
providing a direct current bias to the gate of the second output transistor by a resistor coupled between a gate and a drain of the second output transistor; and
feeding the input signal through a capacitor to the gate of the second output transistor when a frequency of the input signal is above a predetermined threshold, the capacitor coupled between the gate of the second output transistor and an input signal source, the capacitor and the resistor operable to define a signal gain amplification point.

16. The method of claim 15, further comprising the step of defining the signal gain amplification point based on a capacitance between the gate and the drain of the second output transistor.

17. The method of claim 15, further comprising the step of providing an approximately 180 degree phase-shifted version of the input signal into a load of the receiver equalization circuit.

18. The method of claim 15, further comprising the step of defining a peaking ratio and a peaking frequency of the receiver equalization circuit based on a value of the feed-though capacitor and a value of the resistor.

19. The method of claim 15, further comprising the step of feeding, by the feed-through capacitor, an approximately 180 degree phase-shifted version of the input signal to the gate of the second output transistor when a frequency of the input signal is above a predetermined threshold.

20. The method of claim 15, further comprising the step of integrating the receiver equalization circuit into at least one of a mobile phone, a set top box, a music player, a video player, an entertainment unit, a navigation device, a computer, a hand-held personal communication systems (PCS) unit, a portable data unit, and a fixed location data unit.
